(19) United States
(12) Patent Application Publication
(10) Pub. No.: US 2007/0132472 A1
(43) Pub. Date: Jun. 14, 2007

(54) Semiconductor integrated circuit and method for testing the same

(75) Inventor: Yukio Sugimura, Hyogo (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/636,458

(22) Filed: Dec. 11, 2006

(30) Foreign Application Priority Data
Dec. 13, 2005 (JP) 2005-359121

(51) Int. Cl. G01R 31/02

(52) U.S. Cl. 324/763

(57) ABSTRACT

Devices to be tested using the measuring terminal of a semiconductor testing apparatus are increased in number. The devices can be formed by executing a step at which a plurality of integrated circuits are provided on a wafer, a photomask for use in forming the integrated circuits is provided with first to nth device patterns, and test result outputs for use in checking that certain functions of the integrated circuits are normal have mutually different characteristics at the individual integrated circuits which correspond to the first to nth device patterns. This makes it possible to observe the test result outputs of the integrated circuits through the use of the common measuring device (measuring terminal) of the semiconductor testing apparatus and more easily increase the number of the devices to be measured simultaneously.

### BACKGROUND OF THE INVENTION

1. Field of the Invention

The present invention relates to a semiconductor integrated circuit whose number can be increased such that simultaneous testing can be done and to a method for testing the semiconductor integrated circuit.

2. Background Art

FIG. 5 is a block diagram of an example of conventional testing apparatus for semiconductor integrated circuits, in which a case where two devices (semiconductor integrated circuits) are tested simultaneously is presented.

In FIG. 5, reference numeral 21 denotes the semiconductor testing apparatus and reference numerals 22 and 23 denote devices to be measured 1st DUT and 2nd DUT which each have one power supply terminal, one input terminal, and two output terminals.

Reference numeral 24 denotes a power supply which is connected from the semiconductor testing apparatus 21 to the power supply terminals of the devices to be measured 1st DUT 22 and 2nd DUT 23. Reference numeral 25 denotes an input which is connected from the semiconductor testing apparatus 21 to the input terminals of the devices to be measured 1st DUT 22 and 2nd DUT 23. Reference numerals 26 and 27 denote the output terminals of the devices to be measured 1st DUT 22, reference numerals 28 and 29 denote the output terminals of the devices to be measured 2nd DUT 23, and all the output terminals must be separately connected to the semiconductor testing apparatus 21.

Furthermore, techniques are disclosed in which the number of signal lines connected to a semiconductor testing apparatus is decreased by adding a circuit between output terminals and the semiconductor testing apparatus (see JP-A Nos. 2003-84045 and 2002-131382). In JP-A No. 2003-84045 titled “TESTING APPARATUS AND METHOD FOR SEMICONDUCTOR INTEGRATED CIRCUIT”, a technique is described in which the number of measuring terminals is decreased by adding each measured terminal decreasing circuit to each common-specification device. In addition, in JP-A No. 2002-131382 titled “SEMICONDUCTOR TESTING APPARATUS”, a technique is described in which each measuring and computing circuit is provided between each common-specification device and a semiconductor testing apparatus.

With regard to large-scale devices, it has become difficult in recent years to simultaneously measure such devices because the number of pins has been increased. In addition, with small-scale devices, it has been required that the cost of their testing be further reduced and the number of the devices simultaneously measured be further increased.

However, it has been difficult to solve such problems because there has been a limit to the number of measuring terminals of semiconductor testing apparatus, there has been a need to add external circuits in cases where devices which are larger than measuring terminals in number have been measured simultaneously, and so on.

### SUMMARY OF THE INVENTION

An object of the present invention is to provide a semiconductor integrated circuit which has an advantage that the circuit device tested by using the measuring terminal of a semiconductor testing apparatus can be increased in number and a method for testing the semiconductor integrated circuit.

To attain the object, a semiconductor integrated circuit according to a first aspect of the invention is formed such that the integrated circuit is formed plurally on a wafer and the outputs of test results for use in checking that certain functions of the integrated circuits are normal are done from the integrated circuits placed in the predetermined regions on the wafer with the outputs having mutually different characteristics.

According to this configuration, the test result outputs of the plural integrated circuits can be observed by using the common measuring device (measuring terminal) of the semiconductor testing apparatus and the number of the devices simultaneously measured can be increased more easily.

A semiconductor integrated circuit according to a second aspect of the invention corresponds to the integrated circuit according to the first aspect and can be formed by executing a step at which a photomask for use in forming the integrated circuits is provided with first to nth device patterns and the integrated circuits placed in the predetermined regions on the wafer correspond to the first to nth device patterns.

According to this configuration, the integrated circuits different in characteristics of the test result outputs can be easily formed by using the first and nth device patterns of one photomask.

A semiconductor integrated circuit according to a third aspect of the invention corresponds to that according to the first aspect and has a characteristic that the test results are outputted from the integrated circuits with a time lag made between the individual test results.

A semiconductor integrated circuit according to a fourth aspect of the invention corresponds to that according to the second aspect and has a characteristic that the test results are outputted from the integrated circuits with a time lag made between the individual test results.

According to the third and fourth aspects of the invention, the test result outputs of the integrated circuits corresponding to the first to nth device patterns can be observed by means of the common measuring device with a time difference made between the individual test result outputs.

A semiconductor integrated circuit according to a fifth aspect of the invention corresponds to that according to the first aspect and has a characteristic that the test results are outputted from the integrated circuits with the frequencies of signals which are the test results each converted differently.

A semiconductor integrated circuit according to a sixth aspect of the invention corresponds to that according to the second aspect and has a characteristic that the test results are outputted from the integrated circuits with the frequencies of signals which are the test results each converted differently.

According to the fifth and sixth aspects of the invention, the test result outputs of the integrated circuits corresponding to the first to nth device patterns can be observed by analyzing the frequency components of signals which are the test result outputs through the use of the common measuring device.

A method for testing a semiconductor integrated circuit according to a seventh aspect of the invention is a method for testing the semiconductor integrated circuit according to the first aspect in which the integrated circuits are tested simultaneously by using the differences in the characteristics of the test results each outputted from the individual integrated circuits.

A method for testing a semiconductor integrated circuit according to an eighth aspect of the invention is a method for testing the semiconductor integrated circuit according to the second aspect in which the integrated circuits are tested simultaneously by using the differences in the characteristics of the test results each outputted from the individual integrated circuits.

According to the seventh and eighth aspects of the invention, the test result outputs of the integrated circuits can be observed by using the common measuring device of the semiconductor testing apparatus. That is, by changing the characteristics of the test result outputs of the integrated circuits measured simultaneously on the same substrate, the test result outputs of the integrated circuits can be measured more easily by using the common measuring devices. Because of this, the number of the terminals required for the test can be decreased to reduce the cost of the test, and the number of the devices to be measured simultaneously can be increased.

A method for testing a semiconductor integrated circuit according to a ninth aspect of the invention is a method for testing the semiconductor integrated circuit according to the third aspect in which the test result outputs of the integrated circuits are observed by using the common measuring device through the use of the function that testing inputs are simultaneously provided from a common input device to the integrated circuits and the test results are each outputted from the individual integrated circuits with a time difference made between the test results.

A method for testing a semiconductor integrated circuit according to a tenth aspect of the invention is a method for testing the semiconductor integrated circuit according to the fourth aspect in which the test result outputs of the integrated circuits are observed by using the common measuring device through the use of the function that testing inputs are simultaneously provided from a common input device to the integrated circuits and the test results are each outputted from the individual integrated circuits with a time difference made between the test results.

According to the ninth and tenth aspects of the invention, the test result outputs of the integrated circuits can be observed by using the common measuring device with a time difference made between the test result outputs and advantages which are the same as those described in the seventh and eighth aspects can be obtained.

A method for testing a semiconductor integrated circuit according to an eleventh aspect of the invention is a method for testing the semiconductor integrated circuit according to the fifth aspect in which the test result outputs of the integrated circuits are observed by using the common measuring device through the use of the function that testing inputs are simultaneously provided from a common input device to the integrated circuits and the test results are each outputted from the individual integrated circuits with signals which are the test results differing from one another in frequency.

A method for testing a semiconductor integrated circuit according to a twelfth aspect of the invention is a method for testing the semiconductor integrated circuit according to the sixth aspect in which the test result outputs of the integrated circuits are observed by using the common measuring device through the use of the function that testing inputs are simultaneously provided from a common input device to the integrated circuits and the test results are each outputted from the individual integrated circuits with signals which are the test results differing from one another in frequency.

According to the eleventh and twelfth aspects of the invention, the test result outputs of the integrated circuits can be observed by analyzing the frequency components of the signals through the use of the common measuring device and advantages which are the same as those described in the seventh and eighth aspects can be obtained.

### BRIEF DESCRIPTION OF THE DRAWINGS

FIG. 1A is a schematic diagram of a semiconductor integrated circuit according to an embodiment of the present invention and FIG. 1B is a block diagram of a test on the semiconductor integrated circuit;

FIG. 2 is a waveform plot showing waveforms of voltages at individual components described in the embodiment with reference to FIG. 1B;

FIG. 3A is a schematic diagram of a semiconductor integrated circuit according to another embodiment of the invention and FIG. 3B is a block diagram of a test on the semiconductor integrated circuit;

FIG. 4 is a waveform plot of signals produced through changes in frequency characteristics of signals described in the embodiment of the invention with reference to FIG. 3A; and

FIG. 5 is a block diagram of a test on a conventional semiconductor integrated circuit.

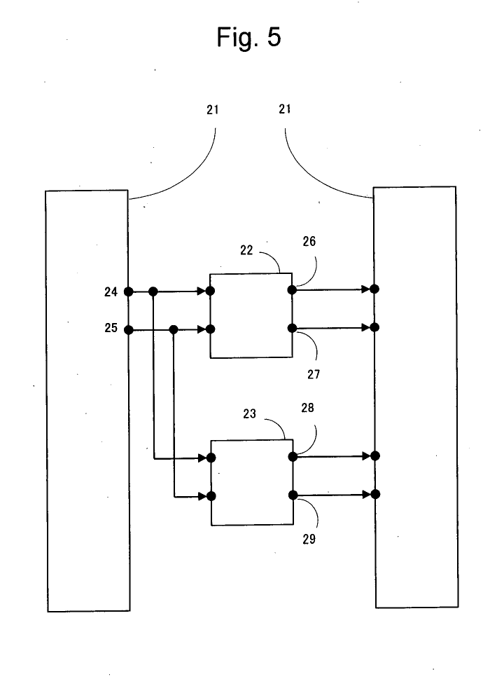

### DESCRIPTION OF THE EXEMPLARY EMBODIMENTS

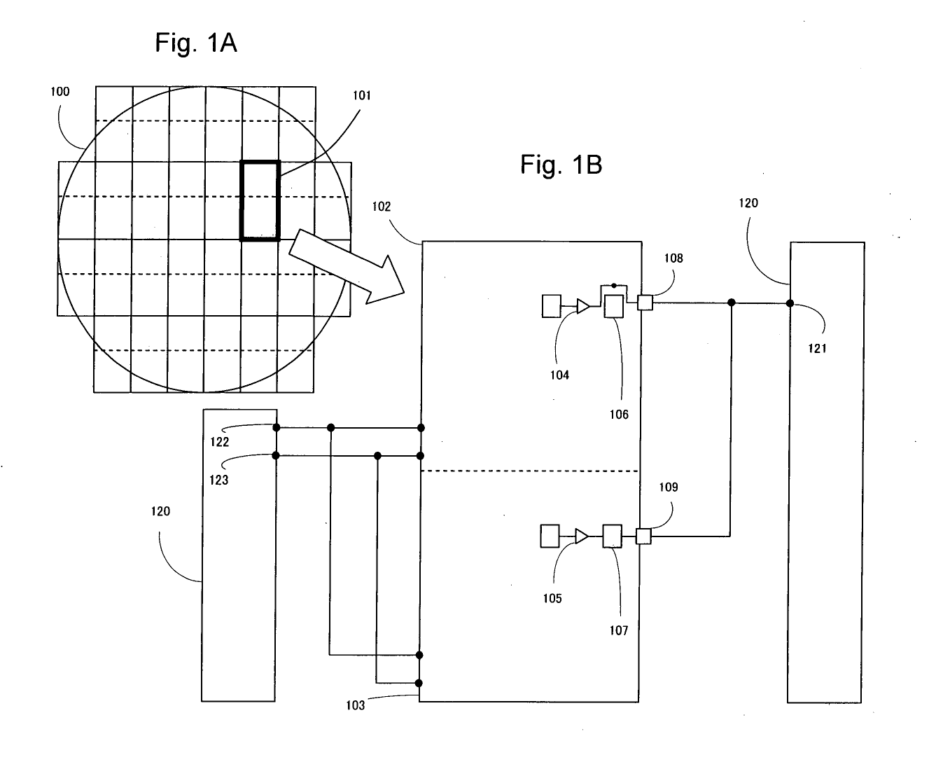

Embodiments of the present invention will be described below with reference to FIGS. 1 to 4.

FIG. 1A is a schematic diagram of a semiconductor integrated circuit according to the embodiment of the invention, and FIG. 1B is a block diagram of a test on the semiconductor integrated circuit of FIG. 1A.

As shown in FIGS. 1A and 1B, a plurality of integrated circuits are provided on a wafer 100 which is fabricated as a substrate on which the semiconductor integrated circuits are to be formed. A photomask for use in forming the integrated circuits is provided with first to nth device patterns. The outputs of test results for use in checking that certain functions of the integrated circuits are normal is produced so as to exhibit different characteristics at the individual integrated circuits which correspond to first to nth device patterns respectively.

In this embodiment, reference numeral 101 of FIGS. 1A and 1B denotes a region which corresponds to one portion of the photomask in forming the devices by using the photomask. In this case, the two patterns, in which the two devices are to be formed, are provided at each portion of the photomask. Reference numeral 102 denotes a device to be measured 1st DUT and this device is an integrated circuit formed using one device pattern of each portion of the photomask. Reference numeral 103 denotes a device to be measured 2nd DUT and this device is an integrated circuit formed using the other device pattern of each portion of the photomask.

Reference numeral 104 denotes a signal 1st DUTOUT in the device to be measured 1st DUT 102. Reference numeral 105 denotes a signal 2nd DUTOUT in the device to be measured 2nd DUT 103. Reference numeral 106 denotes a flip-flop 1st DUTFF in the device to be measured 1st DUT 102 and this flip-flop is not used in the device to be measured 1st DUT 102. Reference numeral 107 denotes a flip-flop 2nd DUTFF in the device to be measured 2nd DUT 103 and this flip-flop receives input from the device to be measured 2nd DUTOUT 105.

Reference numeral 108 denotes an open drain output terminal 1st DUTOD of the device to be measured 1st DUT 102 and this terminal receives the signal 1st DUTOUT 104 as an input. Reference numeral 109 denotes an open drain output terminal 2nd DUTOD of the device to be measured 2nd DUT 103 and this terminal receives output from the flip-flop 2nd DUTFF 107 as input.

Reference numeral 120 denotes a semiconductor testing apparatus. The open drain output terminal 1st DUTOD 108 and the open drain output terminal 2nd DUTOD 109 are connected to a common measuring device (measuring terminal) 121 and pulled up with a function of the semiconductor testing apparatus 120. Reference numeral 122 denotes a power supply which is connected from the semiconductor testing apparatus 120 to the devices to be measured 1st DUT 102 and 2nd DUT 103. Reference numeral 123 denotes an input signal line which is connected from the semiconductor testing apparatus 120 to the devices to be measured 1st DUT 102 and 2nd DUT 103.

The difference between the device to be measured 1st DUT 102 and the device to be measured 2nd DUT 103 is that the flip-flop 1st DUTFF 106 is not connected between the signal 1st DUTOUT 104 and the open drain output terminal 1st DUTOD 108 and the flip-flop 2nd DUTFF 107 is connected between the signal 2nd DUTOUT 105 and the open drain output terminal 2nd DUTOD 109. The device pattern of the flip-flop 1st DUTFF 106 is the same as that of the flip-flop 2nd DUTFF on the photomask, and therefore by providing the integrated circuits 1st DUT 102 and 2nd DUT 103 with mutually different wiring patterns, the characteristics of the circuits exhibited during their test are changed. The difference between their characteristics is effected only in a certain test mode of the devices; that is, the circuits are formed so as to take the very same configuration in a state of their normal operation.

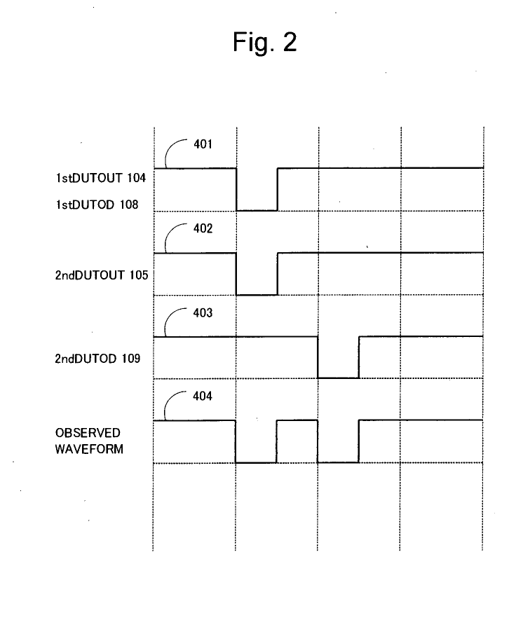

FIG. 2 shows waveforms of voltages at the individual components described in this embodiment with reference to FIG. 1B.

In FIG. 2, reference numeral 401 denotes a first waveform of a voltage at the signal 1st DUTOUT 104 and the open drain output terminal 1st DUTOD 108. Reference numeral 402 denotes a second waveform of a voltage at the signal 2nd DUTOUT 105. Reference numeral 403 denotes a third waveform of a voltage at the open drain output terminal 2nd DUTOD 109 and the third waveform lags the first waveform by one cycle through the provision of the flip-flop 2nd DUTFF 107. Reference numeral 404 denotes a waveform which has been created by overlaying the first and third waveforms with each other and which is observed at the measuring device 121.

According to this embodiment, it becomes possible to observe the signals 1st DUTOUT 104 and 2nd DUTOUT 105—which are expected to have the same output at the devices to be measured 1st DUT 102 and 2nd DUT 103—by using the common measuring device (measuring terminal) 121 with a time lag made between the signals. As a result, the number of the measuring terminals used at the semiconductor testing apparatus 120 can be reduced.

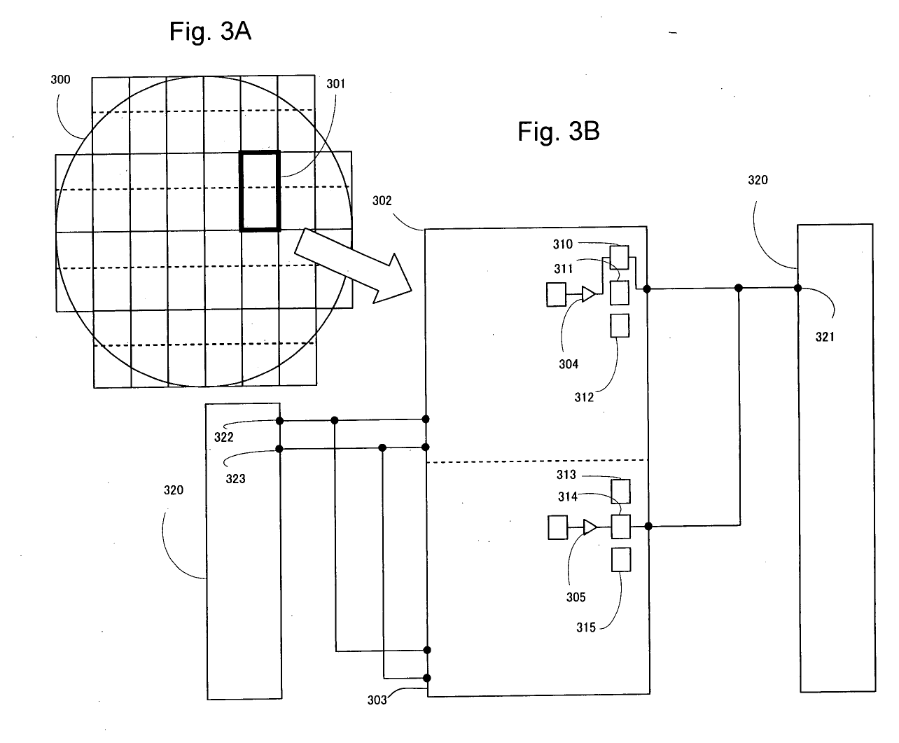

FIGS. 3A and 3B shows a semiconductor integrated circuit according to another embodiment which has been created by modifying the semiconductor integrated circuit of FIGS. 1A and 1B for common use. FIGS. 3A is a schematic diagram of the semiconductor integrated circuit, and FIG. 3B is a block diagram showing a test on the semiconductor integrated circuit.

The semiconductor integrated circuit of FIG. 3B differs from that of FIG. 1B in that a 1st DUT1 testing output 310, a 2nd DUT1 testing output 313, a 1st DUT2 testing output 311, and a 2nd DUT2 testing output 314 are provided instead of the flip-flops 1st DUTFF 106 and 2nd DUTFF 107 and the open drain output terminals 1st DUTOD 108 and 2nd DUTOD 109 and that a 1st DUT normal output 312 and a 2nd DUT normal output 315 produced during normal operation are shown specifically.

In FIG. 3B, since a device to be measured 1st DUT 302 uses the 1st DUT1 testing output and a device to be measured 2nd DUT 303 uses the 2nd DUT2 testing output at the time of testing, test results on the devices to be measured 1st DUT 302 and 2nd DUT 303 can be observed by means of a common measuring device (measuring terminal) 321. On the other hand, since the 1st DUT normal output 312 and the 2nd DUT normal output 315 are used at the time of normal operation, the product is produced in which the devices to be measured 1st DUT 302 and 2nd DUT 303 are identical in their characteristics. There is a need to test the 1st DUT normal output 312 and the 2nd DUT normal output 315 separately (sequentially), but the other internal functions can be simultaneously measured by means of the common measuring device (measuring terminal) 321.

Incidentally, the description that the number of the devices fabricated with mutually different characteristics born is set at two pieces (that is, the 1st DUT 102 and the 2nd DUT 103) and the number of the devices to be simultaneously measured is set at two pieces has been presented in the embodiment described above; however, their number is not limited to two pieces but can be freely set as long as other factors such as a chip size and the number of the terminals of the devices are satisfied.

And further, in the above embodiment, the test result output can be observed through the use of the common measuring terminal by making a time difference between the test results on the devices, while by sending a signal produced by overlaying one signal on another to the common measuring device (measuring terminal) with the frequency characteristics of the signals outputted as the test results changed and by analyzing its specific frequency components at the side of the semiconductor testing apparatus, the test results can also be observed by using the common measuring terminal.

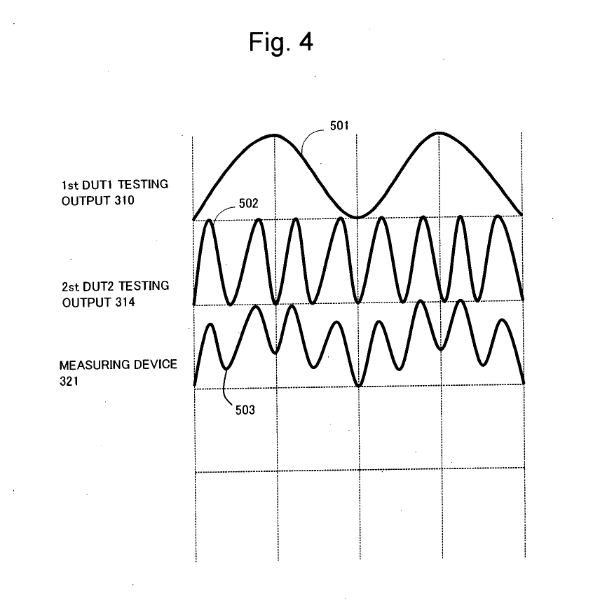

FIG. 4 is a waveform plot of signals produced through changes in the frequency characteristics described in the latter embodiment of the invention.

As shown in FIG. 4, when the 1st DUT1 testing output 310 outputs a signal having a waveform 501 and the 2nd DUT2 testing output 314 outputs a signal have a waveform 502, a waveform 503 is observed at the measuring device 321. The analysis of the waveform 503 observed at the common measuring device 321 makes it possible to determine that the test results are sent from the device to be measured 1st DUT 302 or sent from the device to be measured 2nd DUT 303.

As the 1st DUT1 testing output 310, the 1st DUT2 testing output 311, the 2nd DUT1 testing output 313, and the 2nd DUT2 testing output 314, frequency converters may be used which convert the frequencies of signals outputted as test results 1st DUTOUT 304 and 2nd DUTOUT 305 according to the output characteristics of the test results 1st DUTOUT 304 and 2nd DUTOUT 305, or signal generators may be used which generate signals having specific frequencies through the reception of the outputs of the test results 1st DUTOUT 304 and 2nd DUTOUT 305.

In addition, in this embodiment, the description of measures against cases where an adverse effect is produced on the test on the other devices measured simultaneously, such as a case where one of the devices simultaneously measured shorts out, is omitted for the purpose of clarity; however, even when any device to be measured is faulty, it becomes possible to do testing without problems by taking measures such as the provision of a relay to the power supply made for the purpose of not producing any adverse effect on the system of testing, the conduct of a pretest, and the consideration of the test order of the devices.

1. A semiconductor integrated circuit which can be formed by executing a step at which a plurality of integrated circuits are provided on a wafer and test result outputs for use in checking that certain functions of the integrated circuits are normal are produced so as to have mutually different characteristics at the individual integrated circuits placed in predetermined regions on the wafer.

2. The semiconductor integrated circuit according to claim 1 which can be formed by executing a step at which a photomask for use in forming the integrated circuits is provided with first to nth device patterns and the integrated circuits placed in the predetermined regions on the wafer correspond to the first to nth device patterns.

3. The semiconductor integrated circuit according to claim 1 which has a characteristic that the test result outputs are each done from the individual integrated circuits with a time lag made between the test result outputs.

4. The semiconductor integrated circuit according to claim 2 which has a characteristic that the test result outputs are each done from the individual integrated circuits with a time lag made between the test result outputs.

5. The semiconductor integrated circuit according to claim 1 which has a characteristic that the test result outputs are each done from the individual integrated circuits with the frequencies of signals which are the test results each converted differently.

6. The semiconductor integrated circuit according to claim 2 which has a characteristic that the test result outputs are each done from the individual integrated circuits with the frequencies of signals which are the test results each converted differently.

7. A method for testing a semiconductor integrated circuit which is a method for testing the semiconductor integrated circuit according to claim 1, wherein the integrated circuits are tested simultaneously through the use of differences in the characteristics of the test result outputs each done at the individual integrated circuits.

8. A method for testing a semiconductor integrated circuit which is a method for testing the semiconductor integrated circuit according to claim 2, wherein the integrated circuits are tested simultaneously through the use of differences in the characteristics of the test result outputs each done at the individual integrated circuits.

9. A method for testing a semiconductor integrated circuit which is a method for testing the semiconductor integrated circuit according to claim 3, wherein the test result outputs of the integrated circuits are observed by using a common measuring device through the use of a function that testing inputs are simultaneously provided from a common input device to the integrated circuits and the test results are each outputted from the individual integrated circuits with the time difference made between the test results.

10. A method for testing a semiconductor integrated circuit which is a method for testing the semiconductor integrated circuit according to claim 4, wherein the test result outputs of the integrated circuits are observed by using a common measuring device through the use of a function that testing inputs are simultaneously provided from a common input device to the integrated circuits and the test results are each outputted from the individual integrated circuits with the time difference made between the test results.

11. A method for testing a semiconductor integrated circuit which is a method for testing the semiconductor integrated circuit according to claim 5, wherein the test result outputs of the integrated circuits are observed by using a common measuring device through the use of a function that testing inputs are simultaneously provided from a common input device to the integrated circuits and the test results are each outputted from the individual integrated circuits with the signals which are the test results differing from one another in frequency.

12. A method for testing a semiconductor integrated circuit which is a method for testing the semiconductor integrated circuit according to claim 6, wherein the test result outputs of the integrated circuits are observed by using a common measuring device through the use of a function that testing inputs are simultaneously provided from a common input device to the integrated circuits and the test results are each outputted from the individual integrated circuits with the signals which are the test results differing from one another in frequency.
